(19) United States
(12) Patent Application Publication
(10) Pub. No.: US 2021/0320175 A1
(43) Pub. Date: Oct. 14, 2021

(54) TRANSISTOR CIRCUIT WITH ASYMMETRICAL DRAIN AND SOURCE

(71) Applicant: QUALCOMM Incorporated, San Diego, CA (US)

(72) Inventors: Haining YANG, San Diego, CA (US); John Jianhong ZHU, San Diego, CA (US)

(21) Appl. No.: 16/844,699

(22) Filed: Apr. 9, 2020

(51) Int. Cl. H01L 29/08; H01L 27/092; H01L 29/78; H01L 29/66

(52) U.S. Cl. CPC H01L 29/0847; H01L 29/66795; H01L 29/785; H01L 27/0924

(57) ABSTRACT

The parasitic capacitance of a transistor may be reduced by mismatching the source and drain. Faster low finger count transistors may be achieved with lower drain capacitance and a frequency gain on the D1 inverter as described for the examples herein. In one such example, a transistor includes a source and a drain wherein a length of the source is more than a length of the drain, a width of the source is more than a width of the drain, or a height of the source is more than a height of the drain.

### FIELD OF DISCLOSURE

This disclosure relates generally to transistor circuits, and more specifically, but not exclusively, to transistor circuits with mismatched source and drain configurations.

### BACKGROUND

As complementary metal oxide semiconductor (CMOS) technology scales down to a 5 nm node, the manufacturing process for CMOS transistors becomes more complex and the transistor performance is difficult to further improve. One reason being that a major limitation is caused by the higher parasitic capacitance in the scaled devices, such as transistors. For example, gate to contact capacitance is a major parasitic capacitance, approximately 50% of total device capacitance (not including metal). In general, the contact capacitance and the resistance is a tradeoff with a lower capacitance (C) causing a higher resistance (R). Multi-finger transistors have been extensively used in nano-scale CMOS circuit design due to the increased circuit performance compared to a single finger layout. However choosing a finger width (W f) and number of fingers (N f) to optimize circuit performance is a challenging problem. In a multi-finger transistor, the drain to source current, trans-conductance and effective gate capacitance increase when increasing the number of fingers. Thus, a CMOS transistor circuit performance reacts differently to source R & C and drain R & C, depending on number of gate fingers in the CMOS transistor circuit. Therefore, current multi-finger transistor circuits are slow with higher frequency gains and large drain resistances.

Accordingly, there is a need for systems, apparatus, and methods that overcome the deficiencies of conventional approaches including the methods, system and apparatus provided hereby.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

In one aspect, a transistor comprises: a substrate; a first fin located on a top surface of the substrate; a second fin located on the top surface of the substrate spaced from the first fin; a gate in contact with the substrate, the first fin, and the second fin; a source in contact with the first fin and the second fin; and a drain in contact with the first fin and the second fin, the drain spaced from the source opposite the gate; wherein one of a length of the source is more than a length of the drain, a width of the source is more than a width of the drain, or a height of the source is more than a height of the drain.

In another aspect, a transistor comprises: a substrate; a first fin located on a top surface of the substrate; a second fin located on the top surface of the substrate spaced from the first fin; means for switching in contact with the substrate, the first fin, and the second fin; means for collecting in contact with the first fin and the second fin; and means for emitting in contact with the first fin and the second fin, the means for emitting spaced from the means for collecting opposite the means for switching; wherein one of a length of the means for collecting is more than a length of the means for emitting, a width of the means for collecting is more than a width of the means for emitting, or a height of the means for collecting is more than a height of the means for emitting.

In still another aspect, a method for manufacturing a transistor comprises: providing a substrate; forming a first fin on a top surface of the substrate; forming a second fin on the top surface of the substrate spaced from the first fin; forming a gate on the substrate, the first fin, and the second fin; forming a source on the first fin and the second fin; and forming a drain on the first fin and the second fin, the drain spaced from the source opposite the gate; wherein one of a length of the source is more than a length of the drain, a width of the source is more than a width of the drain, or a height of the source is more than a height of the drain.

Other features and advantages associated with the apparatus and methods disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings which are presented solely for illustration and not limitation of the disclosure, and in which:

FIGS. 1A&B illustrate an exemplary transistor with a shorter length drain in accordance with some examples of the disclosure;

FIGS. 2A&B illustrate an exemplary transistor with a shorter height drain in accordance with some examples of the disclosure;

FIGS. 3A&B illustrate an exemplary transistor with a shorter width drain in accordance with some examples of the disclosure;

FIGS. 4A-C illustrate an exemplary partial method in accordance with some examples of the disclosure;

FIGS. 5A-C illustrate an exemplary partial method in accordance with some examples of the disclosure;

FIG. 6 illustrates an exemplary partial method in accordance with some examples of the disclosure;

FIG. 7 illustrates an exemplary mobile device in accordance with some examples of the disclosure; and

FIG. 8 illustrates various electronic devices that may be integrated with any of the aforementioned methods, devices, semiconductor devices, integrated circuits, die, interposers, packages, or package-on-packages (PoPs) in accordance with some examples of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

The exemplary methods, apparatus, and systems disclosed herein mitigate shortcomings of the conventional methods, apparatus, and systems, as well as other previously unidentified needs. Examples herein include, but are not limited to, a transistor circuit with a low finger count (<4 fingers) and a drain contact shorter than source contact, a transistor circuit with a low finger count (<4 fingers) and a drain contact lower (horizontally spaced and vertically below—different horizontal plane) than a source contact, and a transistor circuit with a low finger count (<4 fingers) and a drain contact narrower than a source contact.

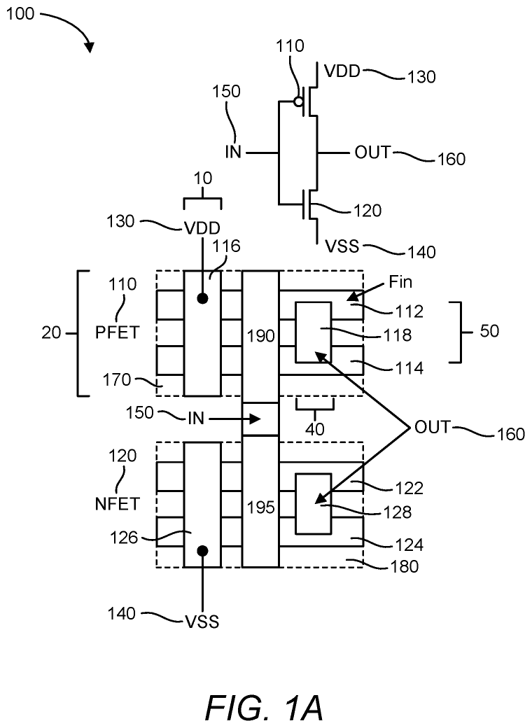

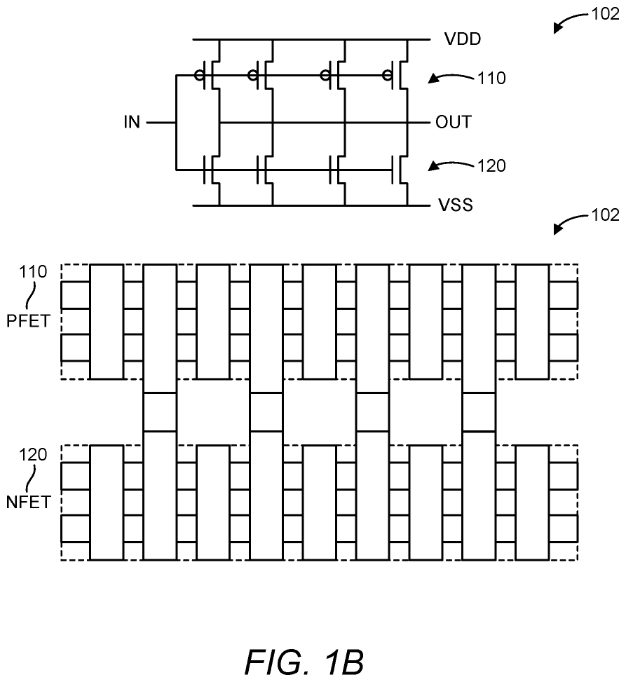

FIGS. 1A&B illustrate an exemplary transistor with a shorter length drain in accordance with some examples of the disclosure. As shown in FIG. 1A, a transistor circuit 100 may include a first transistor 110 coupled to a second transistor 120, a supply voltage 130 (VDD) coupled to the first transistor 110, a ground 140 (VSS) coupled to the second transistor 120, an input 150 coupled to the first transistor 110 and the second transistor 120, and an output 160 coupled to the first transistor 110 and the second transistor 120. The first transistor 110 may include a first fin 112, a second fin 114, a first source 116, and a first drain 118. The second transistor 120 may include a third fin 122, a fourth fin 124, a second source 126, and a second drain 128. The first source 116 has a width 10, a length 20, and a height 30 (not shown but perpendicular to the width 10 and the length 20) and the first drain 118 has a width 40, a length 50, and a height 60 (not shown but perpendicular to the width 40 and the length 50) with the length 20 being 10 to 250 percent more than the length 50. For example, if the length 50 is 22 nm, then the length 20 of the first drain 118 would be approximately 54 nm. While the respective drains and sources for the different transistors are shown as the same, it should be understood that one of the transistors may have asymmetrical drain and source while the other has matched or symmetrical drain and source. The transistor circuit 100 may also include a first substrate 170, a second substrate 180 (the first substrate 170 and the second substrate 180 may be a common substrate), a first gate 190, and a second gate 195 (the first gate 190 and the second gate 195 may be a common gate). As shown, the first transistor 110 is a PFET and the second transistor 120 is an NFET but it should be understood that both could be the same, different, PFETs, NFETs, metal oxide semiconductor transistors, metal oxide semiconductor field effect transistor, or similar and may be optionally integrated or incorporated into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle. As shown in FIG. 1B, the transistor circuit 102 may include multiple first transistors 110 and second transistors 120. One or more of the first transistors 110 and/or the second transistors 120 may have an asymmetrical source and drain as shown in FIG. 1A.

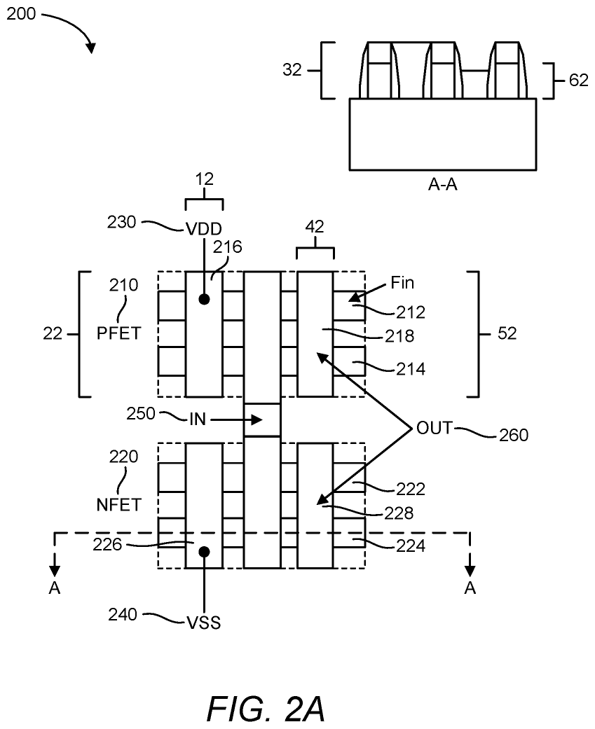

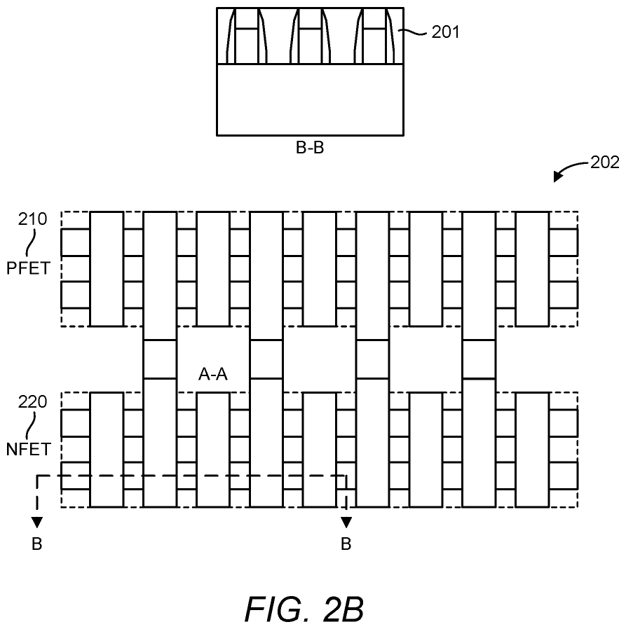

FIGS. 2A&B illustrate an exemplary transistor with a shorter height drain in accordance with some examples of the disclosure. As shown in FIG. 2A, a transistor circuit 200 (e.g., transistor circuit 100) may include a first transistor 210 coupled to a second transistor 220, a supply voltage 230 (VDD) coupled to the first transistor 210, a ground 240 (VSS) coupled to the second transistor 220, an input 250 coupled to the first transistor 210 and the second transistor 220, and an output 260 coupled to the first transistor 210 and the second transistor 220. The first transistor 210 may include a first fin 212, a second fin 214, a first source 216, and a first drain 218. The second transistor 220 may include a third fin 222, a fourth fin 224, a second source 226, and a second drain 228. The first source 216 has a width 12, a length 22, and a height 32 and the first drain 118 has a width 42, a length 52, and a height 62 with the height 32 being 10 to 250 percent more than the height 62. As shown, the first transistor 210 is a PFET and the second transistor 220 is an NFET but it should be understood that both could be the same, different, PFETs, NFETs, metal oxide semiconductor transistors, metal oxide semiconductor field effect transistor, or similar and may be optionally integrated or incorporated into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle. As shown in FIG. 2B, the transistor circuit 202 may include multiple first transistors 210 and second transistors 220. One or more of the first transistors 210 and/or the second transistors 220 may have an asymmetrical source and drain as shown in FIG. 2A and may include an encapsulant or mold compound 201.

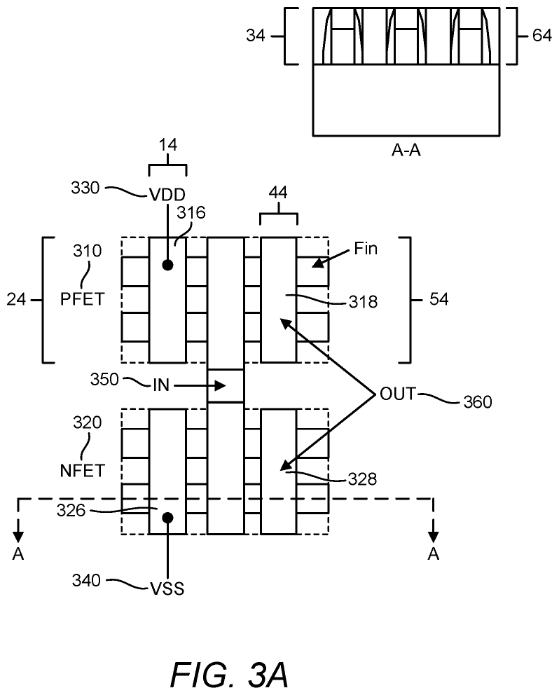

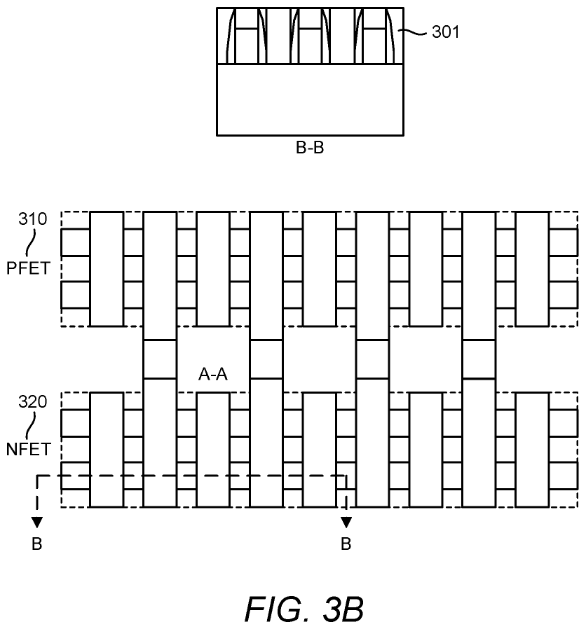

FIGS. 3A&B illustrate an exemplary transistor with a shorter width drain in accordance with some examples of the disclosure. As shown in FIG. 3A, a transistor circuit 300 (e.g., transistor circuit 100) may include a first transistor 310 coupled to a second transistor 320, a supply voltage 330 (VDD) coupled to the first transistor 310, a ground 340 (VSS) coupled to the second transistor 320, an input 350 coupled to the first transistor 310 and the second transistor 320, and an output 360 coupled to the first transistor 310 and the second transistor 320. The first transistor 310 may include a first source 316, and a first drain 318. The second transistor 320 may include a second source 326, and a second drain 328. The first source 316 has a width 14, a length 24, and a height 34 and the first drain 318 has a width 44, a length 54, and a height 64 with the width 14 being 10 to 250 percent more than the width 44. As shown, the first transistor 310 is a PFET and the second transistor 320 is an NFET but it should be understood that both could be the same, different, PFETs, NFETs, metal oxide semiconductor transistors, metal oxide semiconductor field effect transistor, or similar and may be optionally integrated or incorporated into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle. As shown in FIG. 3B, the transistor circuit 302 may include multiple first transistors 310 and second transistors 320. One or more of the first transistors 310 and/or the second transistors 320 may have an asymmetrical source and drain as shown in FIG. 3A and may include an encapsulant or mold compound 301.

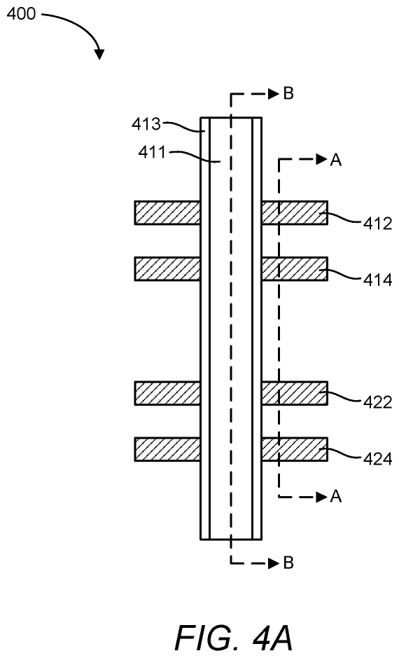

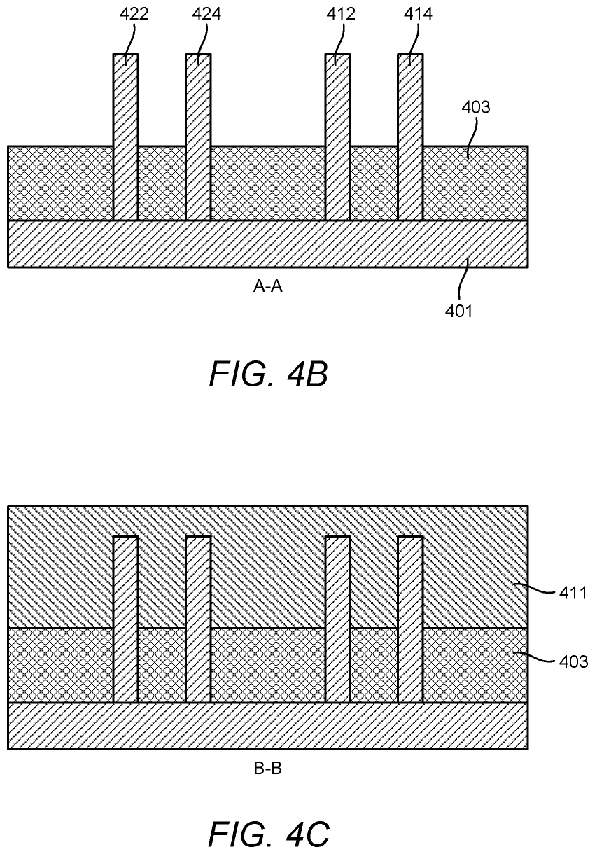

FIGS. 4A-C illustrate an exemplary partial method in accordance with some examples of the disclosure. As shown in FIG. 4A, a partial method 400 for manufacturing a transistor circuit (e.g., transistor circuit 100, 200, or 300) may begin with the formation of a first fin 412 of a first transistor 410, a second fin 414 of the first transistor 410, a third fin 422 of a second transistor 410, a fourth fin 424 of the second transistor 410, a dummy gate 411, and a gate spacer 413 on either side of the dummy gate 411. As shown in FIG. 4B, the partial method 400 may continue with forming an oxide layer 403 on top of the substrate 401. As shown in FIG. 4C, the dummy gate 411 material surround the fins on the oxide layer 403.

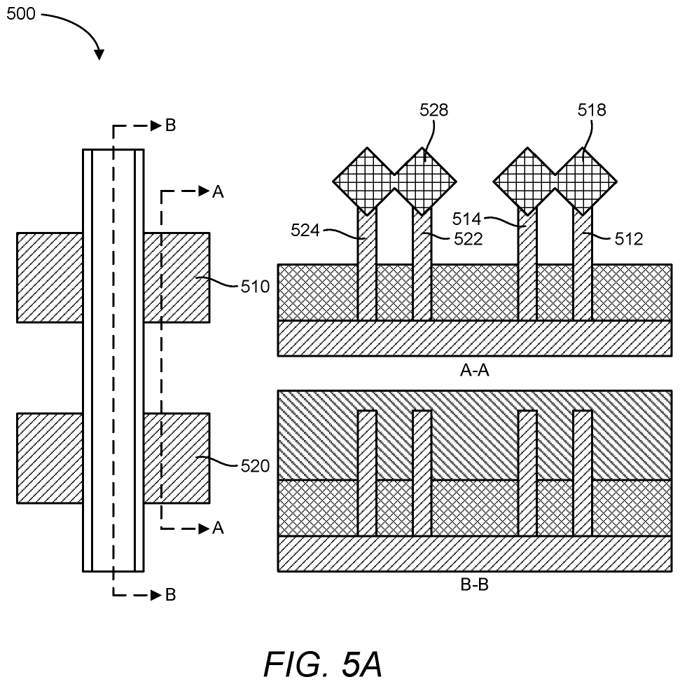

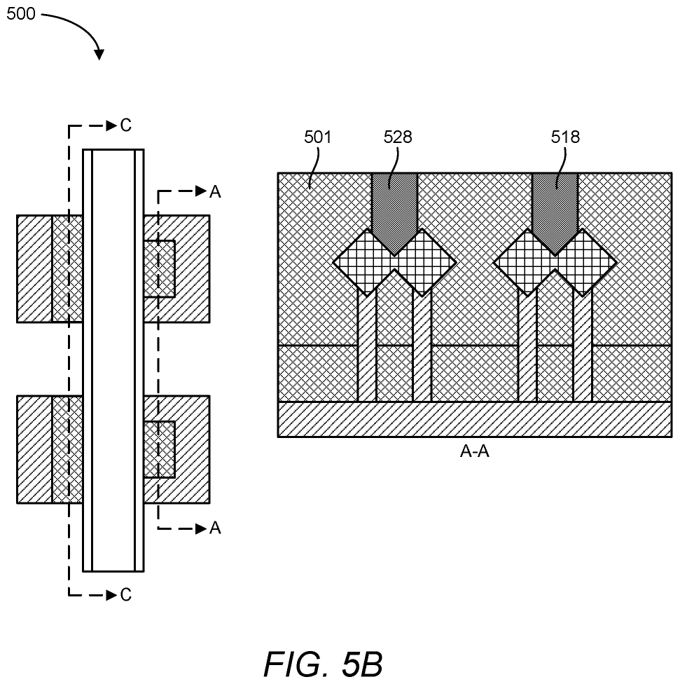

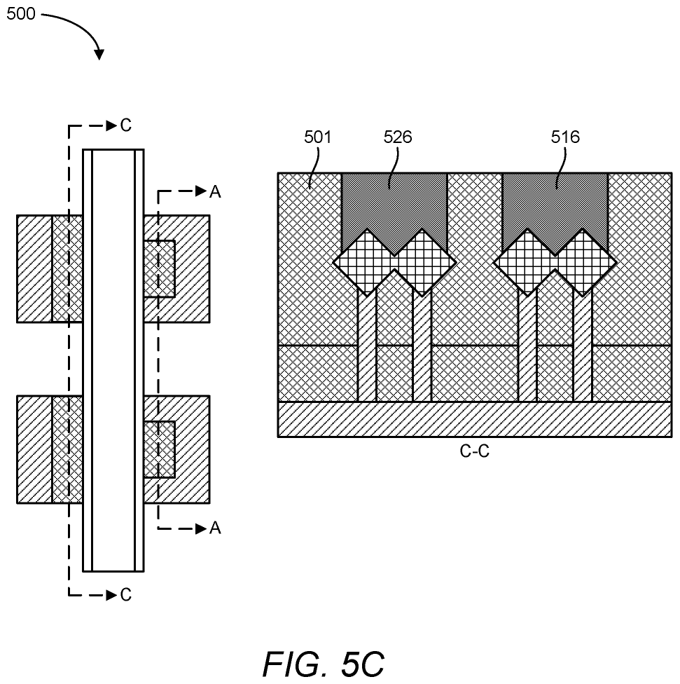

FIGS. 5A-C illustrate an exemplary partial method in accordance with some examples of the disclosure. As shown in FIG. 5A, a partial method 500 for manufacturing a transistor circuit (e.g., transistor circuit 100, 200, or 300) may include epitaxially growing a first drain 518 on the first fin 512 and second fin 514 of a first transistor 510 and epitaxially growing a second drain 528 on the third fin 522 and fourth fin 524 of a second transistor 520. As shown in FIG. 5B, the partial method 500 may continue to epitaxially grow the first drain 518 and the second drain 528 as well as add a mold compound or encapsulant 501. As shown in FIG. 5C, the partial method 500 may include epitaxially growing the first source 516 and the second source 526 as well as adding a mold compound or encapsulant 501.

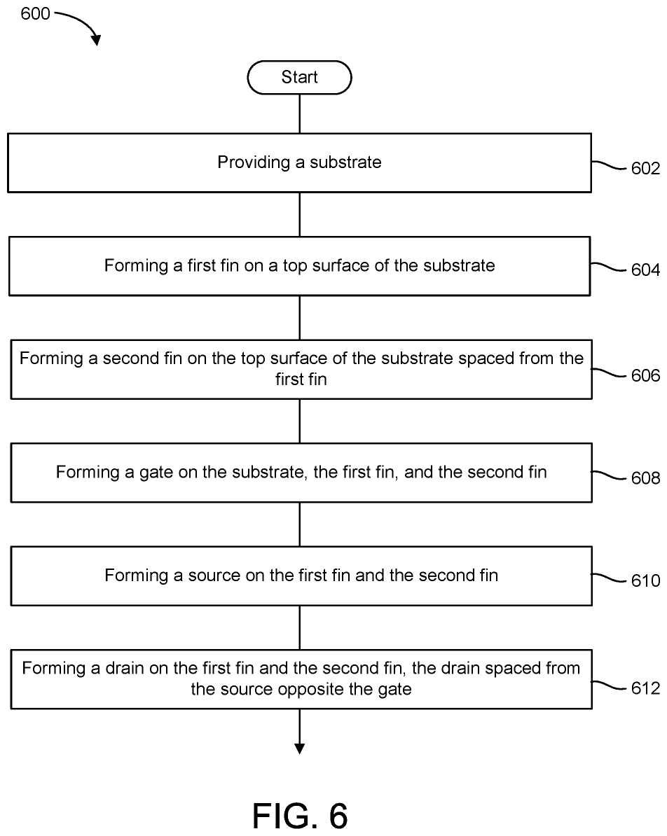

FIG. 6 illustrates an exemplary partial method for manufacturing a transistor circuit in accordance with some examples of the disclosure. As shown in FIG. 6, the partial method 600 may begin in block 602 with providing a substrate. The partial method 600 may continue in block 604 with forming a first fin on a top surface of the substrate. The partial method 600 may continue in block 606 with forming a second fin on the top surface of the substrate spaced from the first fin. The partial method 600 may continue in block 608 with forming a gate on the substrate, the first fin, and the second fin. The partial method 600 may continue in block 610 with forming a source on the first fin and the second fin. The partial method 600 may continue in block 612 with forming a drain on the first fin and the second fin, the drain spaced from the source opposite the gate. Additionally, one of a length of the source is more than a length of the drain, a width of the source is more than a width of the drain, or a height of the source is more than a height of the drain.

Alternatively, the partial method 600 may include wherein the length of the source is at least 10 percent more than the length of the drain; the width of the source is at least 10 percent more than the width of the drain; the height of the source is at least 10 percent more than the height of the drain; the transistor is a metal oxide semiconductor transistor; the transistor is a metal oxide semiconductor field effect transistor; the transistor is configured as an n type transistor; the transistor is configured as a p type transistor; and incorporating the transistor into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.

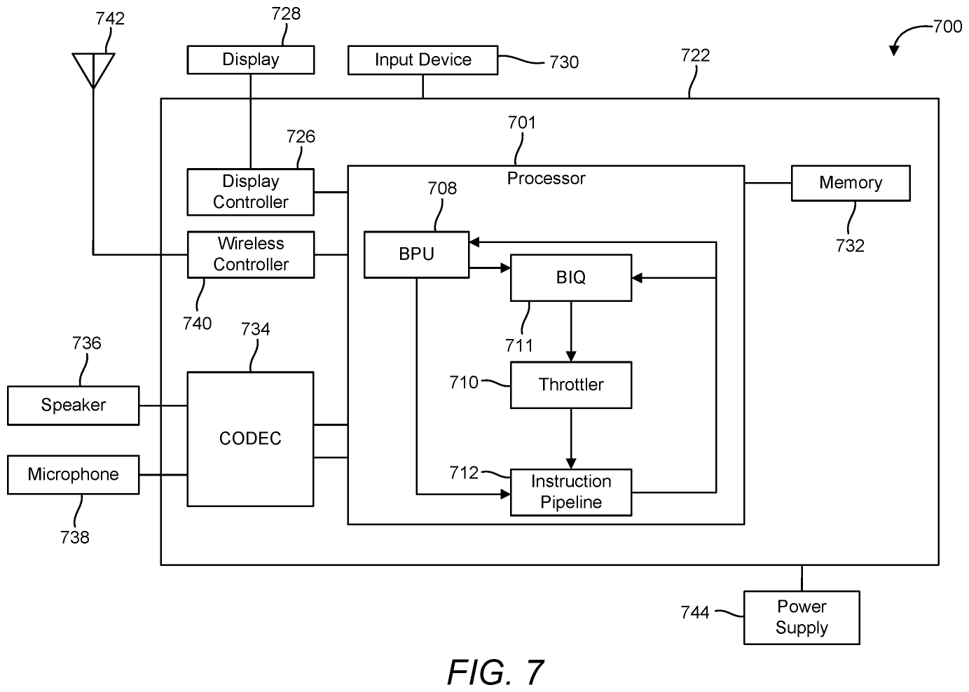

FIG. 7 illustrates an exemplary mobile device in accordance with some examples of the disclosure. Referring now to FIG. 7, a block diagram of a mobile device that is configured according to exemplary aspects is depicted and generally designated 700. In some aspects, mobile device 700 may be configured as a wireless communication device. As shown, mobile device 700 includes processor 701, which may be configured to implement the methods described herein in some aspects. Processor 701 is shown to comprise instruction pipeline 712, buffer processing unit (BPU) 708, branch instruction queue (BIQ) 711, and throttler 710 as is well known in the art. Other well-known details (e.g., counters, entries, confidence fields, weighted sum, comparator, etc.) of these blocks have been omitted from this view of processor 701 for the sake of clarity.

Processor 701 may be communicatively coupled to memory 732 over a link, which may be a die-to-die or chip-to-chip link. Mobile device 700 also include display 728 and display controller 726, with display controller 726 coupled to processor 701 and to display 728.

In some aspects, FIG. 7 may include coder/decoder (CODEC) 734 (e.g., an audio and/or voice CODEC) coupled to processor 701; speaker 736 and microphone 738 coupled to CODEC 734; and wireless controller 740 (which may include a modem) coupled to wireless antenna 742 and to processor 701.

In a particular aspect, where one or more of the above-mentioned blocks are present, processor 701, display controller 726, memory 732, CODEC 734, and wireless controller 740 can be included in a system-in-package or system-on-chip device 722. Input device 730 (e.g., physical or virtual keyboard), power supply 744 (e.g., battery), display 728, input device 730, speaker 736, microphone 738, wireless antenna 742, and power supply 744 may be external to system-on-chip device 722 and may be coupled to a component of system-on-chip device 722, such as an interface or a controller.

It should be noted that although FIG. 7 depicts a mobile device, processor 701 and memory 732 may also be integrated into a set top box, a music player, a video player, an entertainment unit, a navigation device, a personal digital assistant (PDA), a fixed location data unit, a computer, a laptop, a tablet, a communications device, a mobile phone, or other similar devices.

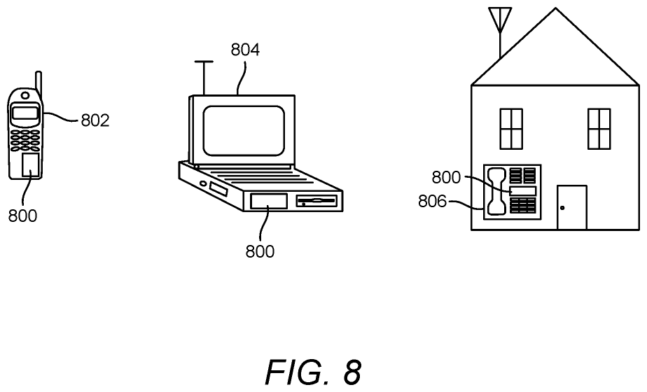

FIG. 8 illustrates various electronic devices that may be integrated with any of the aforementioned integrated device, semiconductor device, integrated circuit, die, interposer, package or package-on-package (PoP) in accordance with some examples of the disclosure. For example, a mobile phone device 802, a laptop computer device 804, and a fixed location terminal device 806 may include an integrated device 800 as described herein. The integrated device 800 may be, for example, any of the integrated circuits, dies, integrated devices, integrated device packages, integrated circuit devices, device packages, integrated circuit (IC) packages, package-on-package devices described herein. The devices 802, 804, 806 illustrated in FIG. 8 are merely exemplary. Other electronic devices may also feature the integrated device 800 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), or any other device that stores or retrieves data or computer instructions, or any combination thereof.

It will be appreciated that various aspects disclosed herein can be described as functional equivalents to the structures, materials and/or devices described and/or recognized by those skilled in the art. It should furthermore be noted that methods, systems, and apparatus disclosed in the description or in the claims can be implemented by a device comprising means for performing the respective actions of this method. For example, in one aspect, a transistor comprises: a substrate; a first fin located on a top surface of the substrate; a second fin located on the top surface of the substrate spaced from the first fin; means for switching (e.g., a gate) in contact with the substrate, the first fin, and the second fin; means for collecting (e.g., a source) in contact with the first fin and the second fin; and means for emitting (e.g., a drain) in contact with the first fin and the second fin, the means for emitting spaced from the means for collecting opposite the means for switching; wherein one of a length of the means for collecting is more than a length of the means for emitting, a width of the means for collecting is more than a width of the means for emitting, or a height of the means for collecting is more than a height of the means for emitting. It will be appreciated that the aforementioned aspects are merely provided as examples and the various aspects claimed are not limited to the specific references and/or illustrations cited as examples.

One or more of the components, processes, features, and/or functions illustrated in FIGS. 1-8 may be rearranged and/or combined into a single component, process, feature or function or incorporated in several components, processes, or functions. Additional elements, components, processes, and/or functions may also be added without departing from the disclosure. It should also be noted that FIGS. 1-8 and its corresponding description in the present disclosure is not limited to dies and/or ICs. In some implementations, FIGS. 1-8 and its corresponding description may be used to manufacture, create, provide, and/or produce integrated devices. In some implementations, a device may include a die, an integrated device, a die package, an integrated circuit (IC), a device package, an integrated circuit (IC) package, a wafer, a semiconductor device, a package on package (PoP) device, and/or an interposer. An active side of a device, such as a die, is the part of the device that contains the active components of the device (e.g. transistors, resistors, capacitors, inductors etc.), which perform the operation or function of the device. The backside of a device is the side of the device opposite the active side.

As used herein, the terms “user equipment” (or “UE”), “user device,” “user terminal,” “client device,” “communication device,” “wireless device,” “wireless communications device,” “handheld device,” “mobile device,” “mobile terminal,” “mobile station,” “handset,” “access terminal,” “subscriber device,” “subscriber terminal,” “subscriber station,” “terminal,” and variants thereof may interchangeably refer to any suitable mobile or stationary device that can receive wireless communication and/or navigation signals. These terms include, but are not limited to, a music player, a video player, an entertainment unit, a navigation device, a communications device, a smartphone, a personal digital assistant, a fixed location terminal, a tablet computer, a computer, a wearable device, a laptop computer, a server, an automotive device in an automotive vehicle, and/or other types of portable electronic devices typically carried by a person and/or having communication capabilities (e.g., wireless, cellular, infrared, short-range radio, etc.). These terms are also intended to include devices which communicate with another device that can receive wireless communication and/or navigation signals such as by short-range wireless, infrared, wireline connection, or other connection, regardless of whether satellite signal reception, assistance data reception, and/or position-related processing occurs at the device or at the other device. In addition, these terms are intended to include all devices, including wireless and wireline communication devices, that are able to communicate with a core network via a radio access network (RAN), and through the core network the UEs can be connected with external networks such as the Internet and with other UEs. Of course, other mechanisms of connecting to the core network and/or the Internet are also possible for the UEs, such as over a wired access network, a wireless local area network (WLAN) (e.g., based on IEEE 802.11, etc.) and so on. UEs can be embodied by any of a number of types of devices including but not limited to printed circuit (PC) cards, compact flash devices, external or internal modems, wireless or wireline phones, smartphones, tablets, tracking devices, asset tags, and so on. A communication link through which UEs can send signals to a RAN is called an uplink channel (e.g., a reverse traffic channel, a reverse control channel, an access channel, etc.). A communication link through which the RAN can send signals to UEs is called a downlink or forward link channel (e.g., a paging channel, a control channel, a broadcast channel, a forward traffic channel, etc.). As used herein the term traffic channel (TCH) can refer to an uplink/reverse or downlink/forward traffic channel.

The wireless communication between electronic devices can be based on different technologies, such as code division multiple access (CDMA), W-CDMA, time division multiple access (TDMA), frequency division multiple access (FDMA), Orthogonal Frequency Division Multiplexing (OFDM), Global System for Mobile Communications (GSM), 3GPP Long Term Evolution (LTE), Bluetooth (BT), Bluetooth Low Energy (BLE), IEEE 802.11 (WiFi), and IEEE 802.15.4 (Zigbee/Thread) or other protocols that may be used in a wireless communications network or a data communications network. Bluetooth Low Energy (also known as Bluetooth LE, BLE, and Bluetooth Smart) is a wireless personal area network technology designed and marketed by the Bluetooth Special Interest Group intended to provide considerably reduced power consumption and cost while maintaining a similar communication range. BLE was merged into the main Bluetooth standard in 2010 with the adoption of the Bluetooth Core Specification Version 4.0 and updated in Bluetooth 5 (both expressly incorporated herein in their entirety).

The word “exemplary” is used herein to mean “serving as an example, instance, or illustration.” Any details described herein as “exemplary” is not to be construed as advantageous over other examples. Likewise, the term “examples” does not mean that all examples include the discussed feature, advantage or mode of operation. Furthermore, a particular feature and/or structure can be combined with one or more other features and/or structures. Moreover, at least a portion of the apparatus described hereby can be configured to perform at least a portion of a method described hereby.

The terminology used herein is for the purpose of describing particular examples and is not intended to be limiting of examples of the disclosure. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, actions, operations, elements, and/or components, but do not preclude the presence or addition of one or more other features, integers, actions, operations, elements, components, and/or groups thereof.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element.

Any reference herein to an element using a designation such as “first,” “second,” and so forth does not limit the quantity and/or order of those elements. Rather, these designations are used as a convenient method of distinguishing between two or more elements and/or instances of an element. Also, unless stated otherwise, a set of elements can comprise one or more elements.

Nothing stated or illustrated depicted in this application is intended to dedicate any component, action, feature, benefit, advantage, or equivalent to the public, regardless of whether the component, action, feature, benefit, advantage, or the equivalent is recited in the claims.

The methods, sequences and/or algorithms described in connection with the examples disclosed herein may be incorporated directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art including non-transitory types of memory or storage mediums. An exemplary storage medium is coupled to the processor such that the processor can read information from, and write information to, the storage medium. In the alternative, the storage medium may be integral to the processor.

Although some aspects have been described in connection with a device, it goes without saying that these aspects also constitute a description of the corresponding method, and so a block or a component of a device should also be understood as a corresponding method action or as a feature of a method action. Analogously thereto, aspects described in connection with or as a method action also constitute a description of a corresponding block or detail or feature of a corresponding device. Some or all of the method actions can be performed by a hardware apparatus (or using a hardware apparatus), such as, for example, a microprocessor, a programmable computer or an electronic circuit. In some examples, some or a plurality of the most important method actions can be performed by such an apparatus.

In the detailed description above it can be seen that different features are grouped together in examples. This manner of disclosure should not be understood as an intention that the claimed examples have more features than are explicitly mentioned in the respective claim. Rather, the disclosure may include fewer than all features of an individual example disclosed. Therefore, the following claims should hereby be deemed to be incorporated in the description, wherein each claim by itself can stand as a separate example. Although each claim by itself can stand as a separate example, it should be noted that-although a dependent claim can refer in the claims to a specific combination with one or a plurality of claims-other examples can also encompass or include a combination of said dependent claim with the subject matter of any other dependent claim or a combination of any feature with other dependent and independent claims. Such combinations are proposed herein, unless it is explicitly expressed that a specific combination is not intended. Furthermore, it is also intended that features of a claim can be included in any other independent claim, even if said claim is not directly dependent on the independent claim.

Furthermore, in some examples, an individual action can be subdivided into a plurality of sub-actions or contain a plurality of sub-actions. Such sub-actions can be contained in the disclosure of the individual action and be part of the disclosure of the individual action.

While the foregoing disclosure shows illustrative examples of the disclosure, it should be noted that various changes and modifications could be made herein without departing from the scope of the disclosure as defined by the appended claims. The functions and/or actions of the method claims in accordance with the examples of the disclosure described herein need not be performed in any particular order. Additionally, well-known elements will not be described in detail or may be omitted so as to not obscure the relevant details of the aspects and examples disclosed herein. Furthermore, although elements of the disclosure may be described or claimed in the singular, the plural is contemplated unless limitation to the singular is explicitly stated.

What is claimed is:

1. A transistor comprising:
a substrate;
a first fin located on a top surface of the substrate;
a second fin located on the top surface of the substrate spaced from the first fin;
a gate in contact with the substrate, the first fin, and the second fin;
a source in contact with the first fin and the second fin; and
a drain in contact with the first fin and the second fin, the drain spaced from the source opposite the gate;
wherein one of a length of the source is more than a length of the drain, a width of the source is more than a width of the drain, or a height of the source is more than a height of the drain.

2. The transistor of claim 1, wherein the length of the source is at least 10 percent more than the length of the drain.

3. The transistor of claim 1, wherein the width of the source is at least 10 percent more than the width of the drain.

4. The transistor of claim 1, wherein the height of the source is at least 10 percent more than the height of the drain.

5. The transistor of claim 1, wherein the transistor is a metal oxide semiconductor transistor.

6. The transistor of claim 1, wherein the transistor is a metal oxide semiconductor field effect transistor.

7. The transistor of claim 1, wherein the transistor is configured as an n type transistor.

8. The transistor of claim 1, wherein the transistor is configured as a p type transistor.

9. The transistor of claim 1, wherein the transistor is incorporated into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.

10. A transistor comprising:
a substrate;
a first fin located on a top surface of the substrate;
a second fin located on the top surface of the substrate spaced from the first fin;
means for switching in contact with the substrate, the first fin, and the second fin;
means for collecting in contact with the first fin and the second fin; and
means for emitting in contact with the first fin and the second fin, the means for emitting spaced from the means for collecting opposite the means for switching;
wherein one of a length of the means for collecting is more than a length of the means for emitting, a width of the means for collecting is more than a width of the means for emitting, or a height of the means for collecting is more than a height of the means for emitting.

11. The transistor of claim 10, wherein the length of the means for collecting is at least 10 percent more than the length of the means for emitting.

12. The transistor of claim 10, wherein the width of the means for collecting is at least 10 percent more than the width of the means for emitting.

13. The transistor of claim 10, wherein the height of the means for collecting is at least 10 percent more than the height of the means for emitting.

14. The transistor of claim 10, wherein the transistor is a metal oxide semiconductor transistor.

15. The transistor of claim 10, wherein the transistor is a metal oxide semiconductor field effect transistor.

16. The transistor of claim 10, wherein the transistor is configured as an n type transistor.

17. The transistor of claim 10, wherein the transistor is configured as a p type transistor.

18. The transistor of claim 10, wherein the transistor is incorporated into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.

19. A method for manufacturing a transistor, the method comprising:
providing a substrate;
forming a first fin on a top surface of the substrate;
forming a second fin on the top surface of the substrate spaced from the first fin;
forming a gate on the substrate, the first fin, and the second fin;
forming a source on the first fin and the second fin; and
forming a drain on the first fin and the second fin, the drain spaced from the source opposite the gate;
wherein one of a length of the source is more than a length of the drain, a width of the source is more than a width of the drain, or a height of the source is more than a height of the drain.

20. The method of claim 19, wherein the length of the source is at least 10 percent more than the length of the drain.

21. The method of claim 19, wherein the width of the source is at least 10 percent more than the width of the drain.

22. The method of claim 19, wherein the height of the source is at least 10 percent more than the height of the drain.

23. The method of claim 19, wherein the transistor is a metal oxide semiconductor transistor.

24. The method of claim 19, wherein the transistor is a metal oxide semiconductor field effect transistor.

25. The method of claim 19, wherein the transistor is configured as an n type transistor.

26. The method of claim 19, wherein the transistor is configured as a p type transistor.

27. The method of claim 19, wherein the method further comprises incorporating the transistor into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.
